(19) United States
(12) Patent Application Publication
(10) Pub. No.: US 2010/0083901 A1
(43) Pub. Date: Apr. 8, 2010

(54) Arrangement for Producing Coatings on Substrates in Vacuo

(76) Inventor: Carl Friedrich Meyer, Dresden (DE)

Correspondence Address: Kaplan Gilman & Pergament LLP, 1480 Route 9 North, Woodbridge, NJ, 07095, US

(21) Appl. No.: 12/597,189

(22) PCT Filed: Apr. 21, 2008
(86) PCT No.: PCT/DE08/00727

§ 371 Date: Dec. 15, 2009

(30) Foreign Application Priority Data
Apr. 23, 2007 (DE) 10 2007 019 982.3

(51) Int. Cl. C23C 16/00

(52) U.S. Cl. 118/723 E

(57) ABSTRACT

The invention relates to an assembly for the formation of coatings on substrates in a vacuum, wherein a plasma is formed by means of electric arc discharge at least on one target connected as cathode, and the arc discharge will be ignited between an anode and the target by means of a deflectable focused laser beam which is directed through a window to the surface of the target. It is an object of the invention to provide a technical solution by means of which an undesired coating in the window area of a vacuum chamber can be distinctly reduced. According to the invention, for this a permanent magnet or electromagnet is disposed between the window and at least one target at the side next to, above or below the optical axis of the laser beam, and the laser beam is guided through a magnetic field developed by the permanent magnet or electromagnet.

The invention relates to an assembly for the formation of coatings on substrates in a vacuum, wherein a plasma is formed by means of electric arc discharge on at least one target connected as cathode, and the arc discharge is ignited between an anode and the target by means of a deflectable focused laser beam being directed to the surface of the target. The laser beam emitted from a laser light source disposed outside a vacuum chamber is then directed through a window being present on the vacuum chamber into the vacuum chamber, and so to the surface of the respective target.

Thus, arc discharges can be ignited starting from the surface of a target in different positions to be able to achieve uniform material abrasion across a useful surface of a target. Thus, targets disposed inside of the vacuum chambers can be used over longer operating times, and at the same time a uniform coating formation can be achieved.

The deflection of such a laser beam can be achieved through conventional systems such as scanner systems or other suitable and movable reflecting elements.

Such a technical solution is described in DE 19850217 C1, inter alia, and the procedure according to that is also referred to as “Laser-Arc method”.

Then, it cannot be avoided that certain parts of the formed plasma are vagabonding inside of the vacuum chamber, and as a result it may come to a deposition of coating material inside of the vacuum chamber as well, and on such windows accordingly. The windows will also be provided with a coat as well. Because of that, the transparency of the windows reduces in an undesired form such that they have to be cleaned more or less frequently or even have to be substituted. In order to counteract these disadvantages window protective foils have been used which are disposed in the vacuum chamber consequently protecting the windows from a coating, however, and which will also be coated. Such window protective foils are available as reels, and will be uncoiled from a supply-spool and be coiled on a second spool in operation of a respective coating plant, wherein this is performed successively or continuously in operation of a plant. As a result, the coiling operation is carried out with a speed of approximately two metres per hour. The supply of such a foil inside of a vacuum chamber is limited in that the water and other gases are included inside of a foil spool which can outgas, and which undesirably influence the vacuum conditions. Accordingly, the replacement of a spool is required after about 15 operating hours. Because of the time required for the replacement and the expenses for the window protective foil as well, of course, the costs of fabrication increase accordingly.

Therefore, it is an object of the invention to provide a technical solution by means of which undesired coating in the window area can be distinctly reduced.

According to the invention, this object is solved with an assembly comprising the features of claim 1. Advantageous embodiments and improvements of the invention can be achieved with the features indicated in the subordinate claims.

An assembly according to the invention for the formation of coatings on substrates in a vacuum in which it is enabled to operate with the “Laser-Arc Method” as is known from the prior art, is improved in that at least one permanent magnet or electromagnet is disposed between the window and at least one target. Then, at least one permanent magnet or electromagnet is positioned at the side next to or above and below the optical axis of the laser beam, respectively, and as a result a magnetic field is developed by the permanent magnet or electromagnet. Because of the magnetic field the laser beam can be directed in the direction to the surface of the target.

The magnetic field developed by one or a plurality of permanent magnets or electromagnet(s) each should have one field component which is aligned normal to the optical axis of the laser beam and/or to the plane in which the laser beam will be deflected.

As already touched on in the introducing part of the description, the laser beam can be deflected, wherein this can be preferably performed through an oscillating motion between inversion points in a plane. Accordingly, a window on the vacuum chamber should have an adequate shape and dimensioning by means of which it can be ensured that the laser beam is able to scan the entire length of targets during the deflection.

For improved protection, inside of the vacuum chamber between the window and permanent magnet or electromagnet(s) an aperture can be disposed through the opening of which the laser beam is allowed to be passed through for the ignition of arc discharges.

In an improvement of the invention, as this is known from the prior art, a window protective foil can be disposed in front of the window preferably between the aperture and window, which can be uncoiled from a supply-reel and can be coiled on another reel as well in a per se known manner.

With the magnetic field(s) the plasma and also target material can be deflected such that it cannot pass in the direction to the window and window protective foil, respectively, through which there the coating in this area at least can be considerably reduced.

The protection from undesired coating can also be increased in that, besides the already mentioned aperture, a second aperture is disposed inside of the vacuum chamber.

Then, between the target and the first aperture and window protective foil, respectively, or the window a second aperture can be disposed as a separate aperture having an opening through which the laser beam can be directed to the target for the ignition of arc discharges. As a result, such an aperture is disposed in the immediate vicinity of targets then.

In another alternative according to the invention such an aperture can also be provided with a corresponding assembly of at least two permanent magnets or electromagnets which are then disposed such that they form a gap which, more or less, can form an opening of an aperture. Thus, two permanent magnets or electromagnets can be disposed such that one permanent magnet or electromagnet is disposed on one side of the optical axis, and a second permanent magnet or electromagnet is disposed on an opposite side of the optical axis of the laser beam. Then, they can be aligned in parallel to each other.

With the invention the permanent magnets or electromagnets should be disposed such that they have the same pole alignment each.

Then, there is a possibility to stagger at least two permanent magnets or electromagnets between the window and the target such that they each have different distances to the target or rather to the window.

Further it is favourable that the individual elements being serviceable with the assembly according to the invention that is the apertures and permanent magnets or electromagnets are disposed and formed considering the dimensioning of targets.

With the invention, it is possible to be precise to merely use just one target by means of which plasma can be formed for coating of substrates. However, in another alternative a plurality of targets preferably in a line-in assembly can be provided. With a plurality of such targets then multilayer systems can be formed on substrates, wherein targets from different substances or mixtures of substances will be used.

Then, targets can be formed in a roller like shape or cylindrically, and rotate about an axis during the formation of coatings by means of which a uniform abrasion of target material can be further supported with the plasma formation.

As already indicated, the lengths of apertures and the width of the permanent magnets or electromagnets used according to the invention as well should then take into consideration the respective target length. Accordingly, the aperture openings or the widths of the permanent magnets and electromagnets should correspond at least to the length of one target or to the overall length of a plurality of targets disposed in an in-line arrangement such that a laser beam can be deflected over the entire length of one target or a plurality of targets, and protection from undesired coating can be achieved.

As already touched on, the laser beam can be oscillated in a plane and can thus be deflected. In this case the optical axis of the laser beam is positioned in that plane in which the deflection is performed.

In the following, the invention shall be explained in more detail by way of example.

In the drawings,

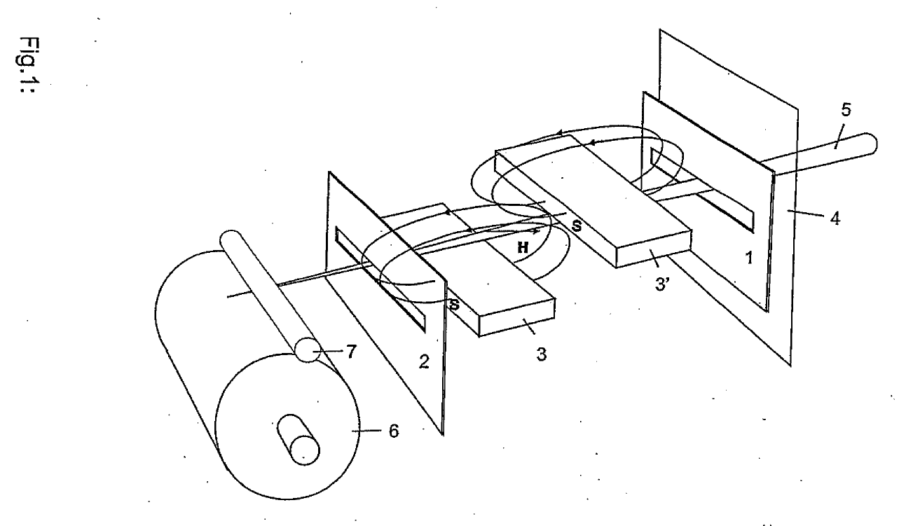

FIG. 1 is an embodiment of an assembly according to the invention in a schematic form;

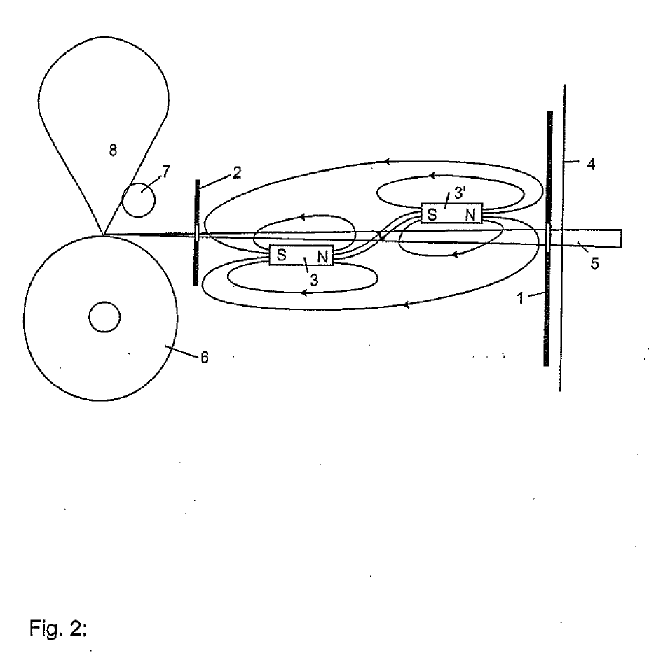

FIG. 2 is a side view of an embodiment of the assembly according to the invention; and

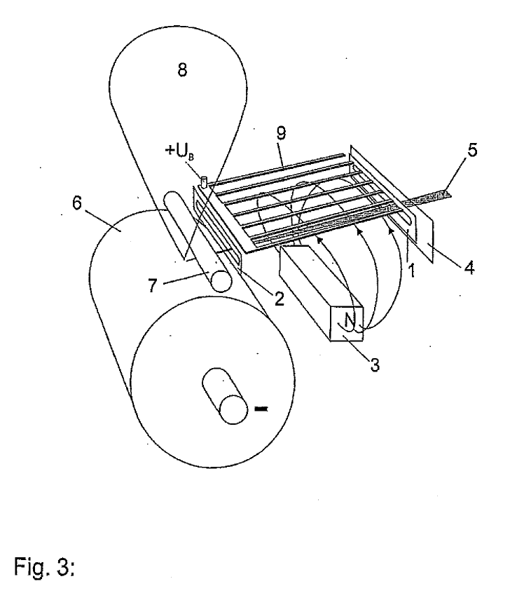

FIG. 3 is another embodiment of an assembly according to the invention.

In the figures it was refrained from representing a vacuum chamber and a window formed thereon through which a laser beam 5 can be directed into the vacuum chamber in the direction to a target 6.

FIG. 1 shows how a laser beam 5 can be directed from a laser light source disposed outside a vacuum chamber through a window and a window protective foil 4, the opening of an aperture 1 and another opening of a second aperture 2 in the direction to a target 6. The openings of the apertures 1 and 2 are then formed in a rectangular shape and have a sufficiently great length such that the laser beam 5 can be deflected across an overall length of one target or a plurality of targets 6.

In the embodiment shown in FIG. 1 the two permanent magnets 3 and 3′ are disposed between the two apertures 1 and 2. As a result, the permanent magnet 3 is disposed below the optical axis of the laser beam 5, and the permanent magnet 3′ is disposed above the optical axis of the laser beam 5. The laser beam 5 can be directed through between the two permanent magnets 3 and 3′ in the direction to the target 6. The aperture 1 has an opening the height of which is about 10 mm, and it is disposed immediately in front of the window protective foil 4. The opening of the aperture 2 has a height of 4 mm, and is disposed immediately in front of the target 6 connected as cathode then.

The two permanent magnets 3 and 3′ are disposed such that they have the same pole alignment in the propagation direction of the laser beam 5. The field lines of the magnet fields of the two permanent magnets 3 and 3′ are drawn in diagrammatically which is also applicable to FIG. 2.

The length of a target 6 which is formed in a roller like form can amount to 200 mm, or it is allowed to be longer too. Consequently, permanent magnets 3 and 3′ can be used the overall length of which at least amounts to the target length of 200 mm. However, at the same time it is also possible for a plurality of permanent magnets having a shorter length then to be arranged in a line wherein the permanent magnets 3 and 3′, respectively, arranged in a line each have the same pole alignment. Thus, for example, with four permanent magnets 3 or 3′ having a respective length of 70 mm and a width of 15 mm an overall length of 280 mm can be achieved.

With FIG. 2 it is further illustrated how the laser beam 5 can be directed via the openings of the apertures 1 and 2, and between the permanent magnets 3 and 3′ to the surface of a cylindrical target 6. Between the target 6 connected as cathode and an anode 7 thus electric arc discharges can be ignited, and as a result a plasma 8 can be formed which can be used again for coating of substrates here not shown inside of a vacuum chamber.

With the invention permanent magnets 3 or 3′ having a magnetic induction of 20 to 50 mT can be used.

In FIG. 3 another embodiment of an assembly according to the invention is shown. Then again, a laser beam 5 for igniting electric arc discharges is shown which is deflectable in a plane in parallel to the surface of a cylindrical target 6 rotating about its longitudinal axis, which is directed to the target 6 through a window not shown herein, a window protective foil 4, through openings of the two apertures 1 and 2.

Here, a permanent magnet 3 is positioned below the plane in which the laser beam 5 will be deflected and/or the optical axis of a non-deflected laser beam 5. The field which is formed by the permanent magnet 3 is aligned in parallel to the anode 2. On the opposite side of the plane or optical axis an element 9 is disposed which, as well as the anode 7, is also electrically connected to an electrical power source. With the element 9, in particular in combination with the field of the permanent magnet, especially of 3 too, plasma 8 passing through the aperture 2, or with the modification without any aperture 2, such plasma 8 reaching in this direction can be additionally deflected such that coating of the window foil 4 can be reduced.

Then, the element 9 can be formed as a single sheet of electrically conducting material. It is allowed as well to be formed grid-like or, such as shown in FIG. 3, provided with strips or strip-shaped as a whole.

Then, the element 9 should be arranged and aligned as well such that the laser beam 5 will not be impeded, however, a magnetic field developed by the element 9 can have its effect to the plasma 8 reaching into this area for its desired deflection away from the window foil 4.

As a result, the element 9 can be aligned in parallel to the plane of deflection or to the optical axis of the laser beam 5. However, there is also a possibility to provide an oblique inclination of the element 9 with a relatively small angle of inclination starting from that side of the element 9 being directed to the target 6 and up to the direction of the aperture 1 and window foil 4.

### SUMMARY

The invention relates to an assembly for the formation of coatings on substrates in a vacuum, wherein a plasma is formed by means of electric arc discharge at least on one target connected as cathode, and the arc discharge will be ignited between an anode and the target by means of a deflectable focused laser beam which is directed through a window to the surface of the target. It is an object of the invention to provide a technical solution by means of which an undesired coating in the window area of a vacuum chamber can be distinctly reduced. According to the invention, for this a permanent magnet or electromagnet is disposed between the window and at least one target at the side next to, above or below the optical axis of the laser beam, and the laser beam is guided through a magnetic field developed by the permanent magnet or electromagnet.

1. An assembly for the formation for coatings on substrates in a vacuum, wherein a plasma is formed by means of electric arc discharge at least on one target connected as cathode, and said arc discharge is ignited between an anode and said at least one target by means of a deflectable laser beam which is directed to the surface of said at least one target, then said laser beam is directed through a window disposed on said vacuum chamber to said at least one target,
wherein between said window and said at least one target at least one permanent magnet or electromagnet is disposed at the side next to, above or below the optical axis of said laser beam and said laser beam is guided through a magnetic field formed by said at least one permanent magnet or electromagnet.

2. The assembly according to claim 1, wherein a magnetic field developed by said at least one permanent magnet or electromagnet has a field component aligned normal to said optical axis of said laser beam and/or to the plane in which said laser beam is deflected.

3. The assembly according to claim 1, wherein between said at least one permanent magnet or electromagnet and said window a first aperture is disposed, through the opening of which the laser beam is directed to said at least one target.

4. The assembly according to claim 1, wherein said at least one permanent magnet or electromagnet comprises a first permanent magnet or electromagnet and a second permanent magnet or electromagnet, said first permanent magnet or electromagnet being disposed at one side of said optical axis and said second permanent magnet or electromagnet being disposed on an opposite side of said optical axis of said laser beam.

5. The assembly according to claim 4, wherein said first and second permanent magnets or electromagnets have the same pole alignment.

6. The assembly according to claim 1, wherein an element connected to an electrically positive potential is arranged on one side disposed opposite to at least said one permanent magnet or electromagnet relative to said optical axis and/or to said plane in which said laser beam is deflected.

7. The assembly according to claim 1, wherein with said at least one permanent magnet or electromagnet a field is developed which is aligned in parallel to said longitudinal axis of said anode.

8. The assembly according to claim 6, wherein said element is formed plate-like, strip-shaped, grid-shaped or provided with strips.

9. The assembly according to claim 6, wherein said element is aligned in parallel to said optical axis of said laser beam and/or to said plane in which said laser beam is deflected.

10. The assembly according to claim 1, wherein said at least one permanent magnet or electromagnet comprises a plurality of magnets or electromagnets that are disposed in a staggered placement between said window and said at least one target.

11. The assembly according to claim 1, wherein two permanent magnets or electromagnets are forming an aperture.

12. The assembly according to claim 1, wherein one window through which said laser beam is guided along across said surface of said at least one target has a length which corresponds to the length of said at least one target considering the alignment of said laser beam.

13. The assembly according to claim 1, wherein said at least one permanent magnet or electromagnet has a width which at least corresponds to the length of said at least one target.

14. The assembly according to claim 3, wherein a second aperture is disposed between said window and said at least one target.

15. The assembly according to claim 14, wherein said openings of said aperture(s) have a length which at least corresponds to the length of said at least one target considering the deflection of said laser beam.

16. The assembly according to claim 15, wherein said opening(s) of said aperture(s) have a width or height which ensure that said laser beam is directed to the surface across the entire length of said at least one target.

17. The assembly according to claim 14, wherein said at least one permanent magnet or electromagnet is arranged between said two apertures.

18. The assembly according to claim 3, wherein between said first aperture and said window a window protective foil is disposed.

19. The assembly according to claim 18, wherein said window protective foil is coilable and uncoilable by means of a mechanism.

20. The assembly according to claim 1, wherein said at least one target is formed as a roll or a cylinder, and said laser beam is directed to the outer circumferential surface of said at least one target.

21. The assembly according to claim 1, wherein said laser beam is deflectable in a plane by means of an oscillating motion.

22. The assembly according to claim 1, wherein said optical axis of said laser beam is located in the plane of the alignment.

23. The assembly according to claim 1, wherein a plurality of said at least one target is disposed in an in-line arrangement.
